(19) United States
(12) Patent Application Publication
(10) Pub. No.: US 2025/0185431 A1
(43) Pub. Date: Jun. 5, 2025

(54) PHOTOELECTRONIC DEVICE WITH MULTIPLE WAVELENGTHS

(71) Applicant: KOREA ADVANCED NANO FAB CENTER, Suwon-si (KR)

(72) Inventors: Hyeong Ho PARK, Daejeon (KR); Eun Jeon YOUN, Suwon-si (KR); Eun-Kyung CHU, Suwon-si (KR)

(73) Assignee: KOREA ADVANCED NANO FAB CENTER, Suwon-si (KR)

(21) Appl. No.: 18/933,135

(22) Filed: Oct. 31, 2024

(30) Foreign Application Priority Data
Dec. 5, 2023 (KR) 10-2023-0174090

(51) Int. Cl. H01L 27/15; H01L 33/00; H01L 33/12; H01L 33/14; H01L 33/30; H01L 33/32; H01L 33/38; H01L 33/44

(52) U.S. Cl. CPC H10H 29/10; H10H 20/013; H10H 20/0133; H10H 20/01335; H10H 20/0137; H10H 20/815; H10H 20/8162; H10H 20/824; H10H 20/825; H10H 20/831; H10H 20/84; H10H 20/032; H10H 20/034

(57) ABSTRACT

Disclosed is an optimal structure that improves the spatial arrangement efficiency of electrodes and further increases luminous efficacy by designing the shape and structure of photo-device portions and controlling open areas. In particular, provided is a full-color RGB pixel that exhibits excellent reproducibility over a large area and can be mass-produced by forming a plurality of photo-device layers, each including an active layer and a common semiconductor layer in a vertical direction, and forming a plurality of photo-device portions in a horizontal direction on a substrate by selective etching and opening processes.

### CROSS-REFERENCE TO PRIOR APPLICATIONS

This application claims priority to Korean Patent Application No. 10-2023-0174090 filed Dec. 5, 2023, which is all hereby incorporated by reference in their entirety.

### BACKGROUND OF THE INVENTION

### Field of the Invention

The present disclosure relates to a photoelectronic device, more specifically, to a photoelectronic device having multiple wavelengths that is imparted with a compact structure and excellent electrical characteristics based on the configuration in which photo-device portions arranged horizontally on a substrate share common semiconductor layers.

Three national projects supported by Korean government associated with this invention are described below.
Project Unique Number: 1415185847
Project Serial Number: 20017391
Government Department: MOTIE (Ministry of Trade, Industry and Energy)
Specialized Institution for Project Management: KEIT (Korea Planning & Evaluation of Industrial Technology)
Title of Research Business: Materials/Parts Package Type
Title of Project: “Development of light source manufacturing technology for micro LED RGB pixels of 360 ppi class stacked structure of 1 inch or more”
Contribution Rate: 1/3
Supervising Institute: Point Engineering Co., Ltd.
Research Period: Jan. 1, 2024˜Dec. 31, 2024
Project Unique Number: 2410000401
Project Serial Number: RS-2023-00257784
Government Department: MOTIE (Ministry of Trade, Industry and Energy)
Specialized Institution for Project Management: KEIT (Korea Planning & Evaluation of Industrial Technology)
Title of Research Business: High performance business of nanoinfrastructure process service
Title of Project: “Development of Process Technology for Nanomaterials and Components in Semiconductor and Display” Contribution Rate: 1/3
Supervising Institute: Korea Electronics Technology Institute
Research Period: Jan. 1, 2024˜Dec. 31, 2024
Project Unique Number: 2410000708
Project Serial Number: RS-2024-00417436
Government Department: MOTIE (Ministry of Trade, Industry and Energy)
Specialized Institution for Project Management: KEIT (Korea Planning & Evaluation of Industrial Technology)
Title of Research Business: The 1st Electronic Component Industrial Technology Development in 2024
Title of Project: “Development of flip-structured microLED chip technology with an external quantum efficiency of more than 50% and a chip size of less than 800 um²”
Contribution Rate: 1/3
Supervising Institute: WaveLord Inc.
Research Period: Apr. 1, 2024˜Dec. 31, 2024

### Description of the Related Art

In accordance with the trend toward high integration and high performance of electric and electronic devices, various attempts are being made to manufacture micro-photoelectronic devices such as micro-light emitting diodes and nano-light emitting diodes.

Recent improvement in high-quality thin film growth technology and device process technology has brought about manufacturing of photoelectronic devices with various sizes. In particular, research is underway on full-color displays using red (R), green (G), and blue (B) micro-light emitting diodes with a size of 100 μm or less.

In conventional methods of realizing full-color displays, RGB pixels are formed using blue micro-light emitting diodes and quantum dots for green- or red-light emission on the blue micro-light emitting diodes. However, commercialization of such methods is limited due to issues such as particle size control of quantum dots, reliability, and limited mass production.

In addition, green and red micro-light-emitting diodes have lower luminous efficacy than blue micro-light-emitting diodes, thus reducing overall efficiency and making it difficult to secure uniformity in color distribution and color reproduction.

In addition, the conventional structure in which red, green, and blue micro-light-emitting diodes are stacked in a vertical direction has problems of color mixing during emission of light from stacked RGB elements, and high driving voltage and leakage current between vertically stacked RGB elements.

In addition, the conventional method requires the areas occupied by each micro-light-emitting diode and the n-electrode and p-electrode for driving each micro-light-emitting diode and thus is not easy to manufacture ultra-small light-emitting diodes required to form large-area, ultra-high-resolution displays, when a full-color pixel is configured based on micro-light-emitting diodes having independent n-electrodes and p-electrodes.

### SUMMARY OF THE INVENTION

Therefore, the present invention has been made in view of the above problems, and it is an object of the present invention to provide a photoelectronic device having multiple wavelengths that is imparted with a compact structure and excellent electrical characteristics based on the configuration in which photo-device portions arranged horizontally on a substrate common semiconductor layers.

In accordance with one aspect of the present invention, the above and other objects can be accomplished by the provision of a photoelectronic device having multiple wavelengths including a first photo-device layer including a lower semiconductor layer, a first active layer, and a first common semiconductor layer on a substrate, a second photo-device layer including a second active layer and a second common semiconductor layer on the first common semiconductor layer, and a third photo-device layer including a third active layer and an upper semiconductor layer on the second common semiconductor layer, a first photo-device portion, a second photo-device portion and a third photo-device portion having the same or different emission wavelengths formed horizontally such that parts of the second common semiconductor layer, the first common semiconductor layer, and the lower semiconductor layer are sequentially opened, and a first electrode formed on the lower semiconductor layer and a second electrode formed on each of the first photo-device portion, the second photo-device portion, and the third photo-device portion, or a first electrode formed in one area on the open lower semiconductor layer, first common semiconductor layer, and second common semiconductor layer, and a second electrode formed on each of the first photo-device portion, the second photo-device portion, and the third photo-device portion.

In addition, the first photo-device portion, the second photo-device portion and the third photo-device portion may operate independently from one another. In addition, the second photo-device portion and the third photo-device portion may horizontally share at least one of the first common semiconductor layer or the second common semiconductor layer 150 and may be formed to operate independently from or in conjunction with each other.

In addition, the second photo-device layer may include a plurality of second photo-device layers formed by repeatedly forming active layers between the common semiconductor layers.

In addition, the open area of the second common semiconductor layer and the first common semiconductor layer may have any one shape of a polygon, a circle, an ellipse, or a bridge.

In addition, the first electrodes formed on the second common semiconductor layer, the first common semiconductor layer and the lower semiconductor layer may be arranged on the same horizontal line and may be connected to each other to form a common electrode.

In addition, the photoelectronic device may further include a passivation film opening an electrode area over an entire area of the photoelectronic device formed before or after forming the first electrode and the second electrode. In addition, the first electrode formed on the lower semiconductor layer may be connected to the first electrode formed in one area of the first common semiconductor layer and the second common semiconductor layer to form a common electrode after forming the passivation film.

In addition, the first electrode and the second electrode may be formed to be flush with each other by adjusting the heights of the first electrode and the second electrode.

In addition, the substrate may include silicon (Si), gallium arsenide (GaAs), gallium phosphide (GaP), gallium arsenide phosphide (GaAsP), boron nitride (BN), SiC, GaN, ZnO, MgO, InP, Ge, InAs, GaSb, sapphire, quartz, or glass.

In addition, the photoelectronic device may further include a buffer layer between the substrate and the lower semiconductor layer. The buffer layer may be a single layer containing any one material of GaAs, Un-GaN, AlN, AlGaN, InAlGaN, SiN, MgN, InN, InAs, AlAs, AlGaAs, InAlGaAs, GaP, InGaAsSb, InGaAsP, AlGaAsP, InGaAlAs, GaSb, AlSb, InAs, InSb, AlGaSb, AlInSb, GaInSb, GaInAsSb, or AlGaInSb, or include a plurality of layers including a combination of two or more layers, or may be a single layer containing two or more materials thereof or include a plurality of layers including a combination of two or more layers.

In addition, the lower semiconductor layer may be an n-type semiconductor layer or a p-type semiconductor layer, and the upper semiconductor layer may be a p-type semiconductor layer or an n-type semiconductor layer. The n-type semiconductor layer may be a single layer containing any one material of n-GaN, n-InGaN, n-AlGaN, n-InAlGaN, n-InAlGaP, n-GaAs, n-AlGaAs, n-InAlGaAs, n-AlGaAsP, n-InGaAsP, n-GaP, n-GaAsP, n-GaInP, n-AlGaInP, n-InGaP, n-InGaAsSb, n-InGaAsP, n-InGaAlAs, n-GaSb, n-AlSb, n-InAs, n-InSb, n-AlGaSb, n-AlInSb, n-GaInSb, n-GaInAsSb, or n-AlGaInSb, or may include a plurality of layers including a combination of two or more layers, or may be a single layer containing two or more materials thereof or may include a plurality of layers including a combination of two or more layers, and the p-type semiconductor layer may be a single layer containing any one material of p-GaN, p-InGaN, p-AlGaN, p-InAlGaN, p-InAlGaP, p-GaAs, p-AlGaAs, n-InAlGaAs, p-AlGaAsP, p-InGaAsP, p-GaP, p-GaAsP, p-GaInP, p-AlGaInP, p-InGaP, p-InGaAsSb, p-InGaAsP, p-InGaAlAs, p-GaSb, p-AlSb, p-InAs, p-InSb, p-AlGaSb, p-AlInSb, p-GaInSb, p-GaInAsSb, or p-AlGaInSb, or may include a plurality of layers including a combination of two or more layers, or may be a single layer containing two or more materials thereof or may include a plurality of layers including a combination of two or more layers.

In addition, the first active layer, the second active layer and the third active layer may be formed by repeatedly depositing a plurality of layers containing a combination of two or more of GaN, InGaN, AlGaN, InAlGaN, InAlGaP, GaAs, AlGaAs, InAlGaAs, AlGaAsP, InGaAsP, GaP, GaAsP, GaInP, AlGaInP, InGaP, InGaAsSb, InGaAsP, InGaAlAs, GaSb, AlSb, InAs, InSb, AlGaSb, AlInSb, GaInSb, GaInAsSb, or AlGaInSb.

In addition, each of the first common semiconductor layer and the second common semiconductor layer may include a tunnel junction layer.

In addition, the first common semiconductor layer and the second common semiconductor layer may include an n-type semiconductor layer and a p-type semiconductor layer formed on and under the tunnel junction layer, respectively. In addition, the photoelectronic device may further include a diffusion prevention layer and an electron blocking layer formed between the p-type semiconductor layer and the first active layer and between the p-type semiconductor layer and the second active layer, when the upper semiconductor layer is a p-type semiconductor layer.

In addition, the first electrode may be formed in any one shape of a polygon, a circle, an ellipse, or a bridge. In addition, the first electrodes may be arranged on the same horizontal line and may be connected to each other to form a common electrode.

### BRIEF DESCRIPTION OF THE DRAWINGS

The above and other objects, features, and other advantages of the present disclosure will be more clearly understood from the following detailed description taken in conjunction with the accompanying drawings, in which:

FIGS. 1A, 1B, 1C, 1D, 1E, 1F, 1G and 1H are schematic diagrams illustrating a method of manufacturing a photoelectronic device according to an embodiment of the present invention;

FIGS. 2A, 2B, 2C, 2D, 2E and 2F to 7A, 7B, 7C, 7D, 7E and 7F are schematic diagrams illustrating photoelectronic devices according to various embodiments of the present invention; and

FIGS. 8A, 8B, 8C, 8D and 8E to 12A, 12B, 12C, 12D and 12E are images showing actual implementation examples of photoelectronic devices according to embodiments of the present invention.

### DETAILED DESCRIPTION OF THE INVENTION

The present invention aims at realizing an optimal structure that improves the spatial arrangement efficiency of electrodes and further increases luminous efficacy by designing the shape and structure of photo-device portions and controlling open areas.

In particular, the present invention provides a full-color RGB pixel that exhibits excellent reproducibility over a large area and can be mass-produced by forming a plurality of photo-device layers, each including an active layer and a common semiconductor layer in a vertical direction, and forming a plurality of photo-device portions in a horizontal direction on a substrate by selective etching and opening processes.

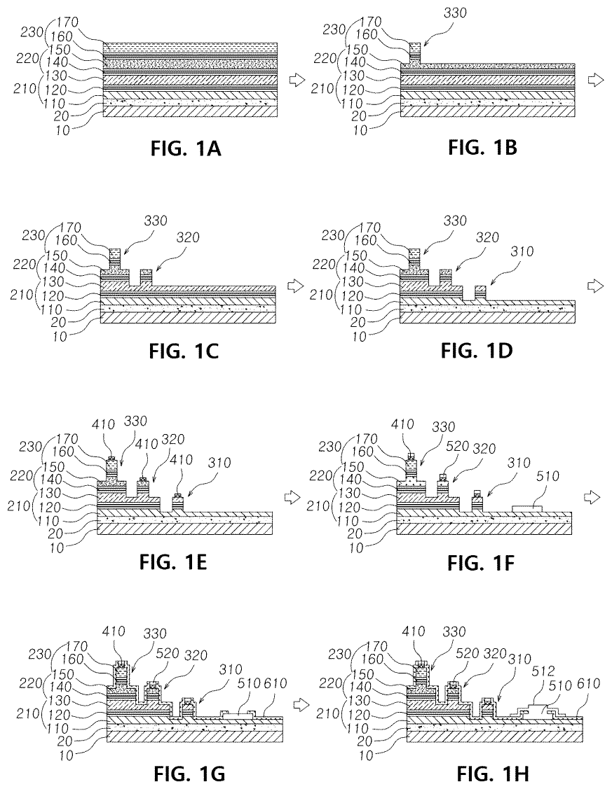

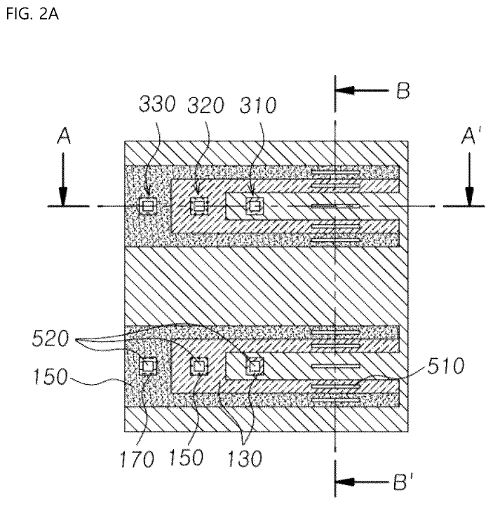

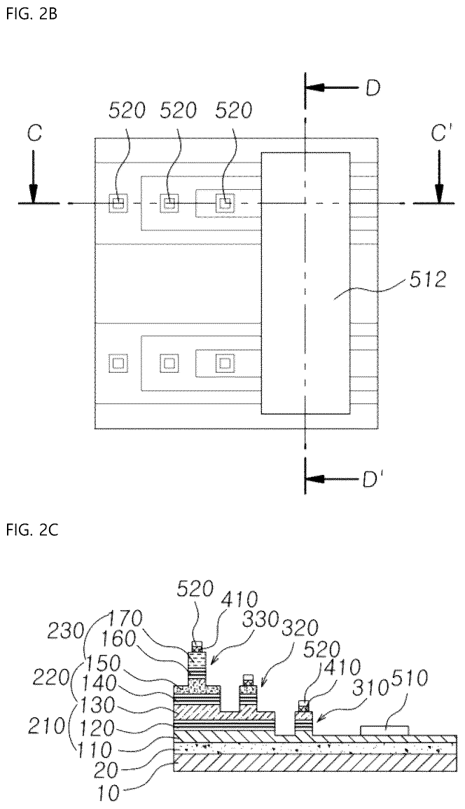

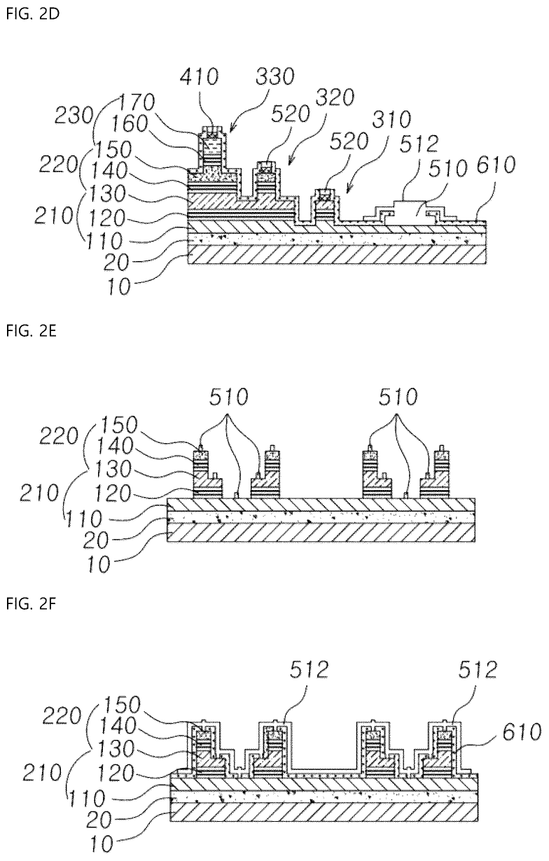

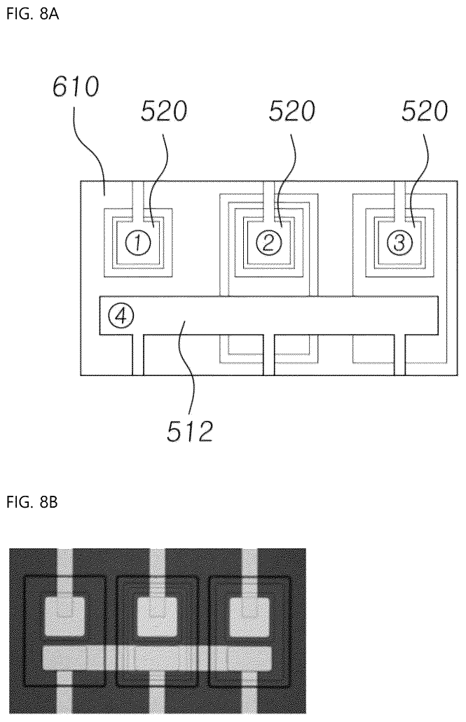

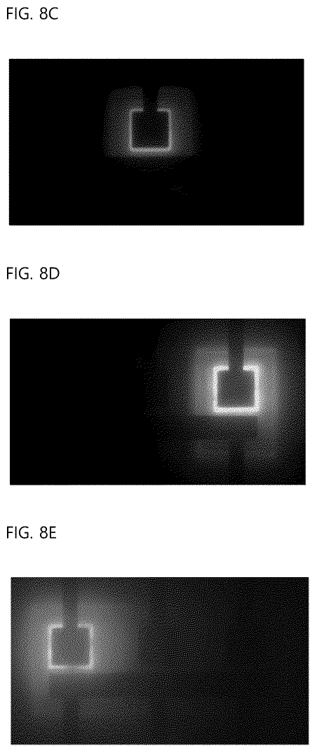

Hereinafter, embodiments of the present invention will be described in detail with reference to the attached drawings. FIGS. 1A, 1B, 1C, 1D, 1E, 1F, 1G and 1H are schematic diagrams illustrating a method of manufacturing a photoelectronic device according to an embodiment of the present invention. FIGS. 2A, 2B, 2C, 2D, 2E and 2F to 7A, 7B, 7C, 7D, 7E and 7F are schematic diagrams illustrating photoelectronic devices according to various embodiments of the present invention. FIGS. 8A, 8B, 8C, 8D and 8E to 12A, 12B, 12C, 12D and 12E are images showing actual implementation examples of photoelectronic devices according to embodiments of the present invention.

As shown in FIGS. 1A, 1B, 1C, 1D, 1E, 1F, 1G and 1H, a photoelectronic device having multiple wavelengths according to an embodiment of the present invention includes: a first photo-device layer 210 including a lower semiconductor layer 110, a first active layer 120, and a first common semiconductor layer 130 on a substrate 10, a second photo-device layer 220 including a second active layer 140 and a second common semiconductor layer 150 on the first common semiconductor layer 130, and a third photo-device layer 230 including a third active layer 160 and an upper semiconductor layer 170 on the second common semiconductor layer 150; a first photo-device portion 310, a second photo-device portion 320 and a third photo-device portion 330 having the same or different emission wavelengths formed horizontally such that parts of the second common semiconductor layer 150, the first common semiconductor layer 130, and the lower semiconductor layer 110 are sequentially opened; and a first electrode 510 formed on the lower semiconductor layer 110, and a second electrode 520 formed on each of the first photo-device portion 310, the second photo-device portion 320, and the third photo-device portion 330, or a first electrode 510 formed in one area on the open lower semiconductor layer 110, the open first common semiconductor layer 130, and the open second common semiconductor layer 150, and a second electrode 520 formed on each of the first photo-device portion 310, the second photo-device portion 320, and the third photo-device portion 330.

The light-emitting device according to the present invention may be applied to a light emitting diode (LED), a micro-light emitting diode (micro-LED), a nano-light emitting diode (nano-LED), an ultraviolet light emitting diode (ultraviolet LED), an infrared light emitting diode (infrared LED), a laser diode (LD), a photodiode (PD), an avalanche photodiode (APD), or the like, using III-V, II-VI, and IV-IV compound semiconductors, or semiconductors containing a mixture thereof.

As such, the present invention provides a full-color RGB pixel that exhibits excellent reproducibility over a large area and can be mass-produced by forming a plurality of photo-device layers, each including an active layer and a common semiconductor layer, in a vertical direction, and forming a plurality of photo-device portions in a horizontal direction on a substrate by selective etching and opening processes.

According to an embodiment of the present invention, first, a lower semiconductor layer 110, a first active layer 120, and a first common semiconductor layer 130 are formed on a substrate 10 to realize a first photo-device layer 210, a second active layer 140 and a second common semiconductor layer 150 are formed on the first common semiconductor layer 130 to realize a second photo-device layer 220, and a third active layer 160 and an upper semiconductor layer 170 are formed on the second common semiconductor layer 150 to realize a third photo-device layer 230 (FIG. 1A).

In addition, a plurality of second photo-device layers 220 may be formed by repeatedly performing a process of forming an active layer between common semiconductor layers. Here, the plurality of second photo-device layers 220 may have the same or different emission wavelengths.

The substrate 10 according to one embodiment of the present invention includes a substrate used in the process of manufacturing a semiconductor device, or includes a thin film formed on the substrate 10, and may be silicon (Si), gallium arsenide (GaAs), gallium phosphide (Gap), gallium arsenide phosphide (GaAsP), boron nitride (BN), SiC, GaN, ZnO, MgO, InP, Ge, InAs, GaSb, sapphire, quartz, or glass.

The lower semiconductor layer 110 may be an n-type semiconductor layer or a p-type semiconductor layer, and the upper semiconductor layer 170 may be a p-type semiconductor layer or an n-type semiconductor layer.

Here, the n-type semiconductor layer may be a single layer containing any one material of n-GaN, n-InGaN, n-AlGaN, n-InAlGaN, n-InAlGaP, n-GaAs, n-AlGaAs, n-InAlGaAs, n-AlGaAsP, n-InGaAsP, n-GaP, n-GaAsP, n-GaInP, n-AlGaInP, n-InGaP, n-InGaAsSb, n-InGaAsP, n-InGaAlAs, n-GaSb, n-AlSb, n-InAs, n-InSb, n-AlGaSb, n-AlInSb, n-GaInSb, n-GaInAsSb, or n-AlGaInSb, or include a plurality of layers including a combination of two or more layers, or a single layer containing two or more materials thereof or include a plurality of layers including a combination of two or more layers.

In addition, the p-type semiconductor layer may be a single layer containing any one material of p-GaN, p-InGaN, p-AlGaN, p-InAlGaN, p-InAlGaP, p-GaAs, p-AlGaAs, n-InAlGaAs, p-AlGaAsP, p-InGaAsP, p-GaP, p-GaAsP, p-GaInP, p-AlGaInP, p-InGaP, p-InGaAsSb, p-InGaAsP, p-InGaAlAs, p-GaSb, p-AlSb, p-InAs, p-InSb, p-AlGaSb, p-AlInSb, p-GaInSb, p-GaInAsSb, or p-AlGaInSb, or include a plurality of layers including a combination of two or more layers, or a single layer containing two or more materials thereof or include a plurality of layers including a combination of two or more layers.

In addition, the lower semiconductor layer 110 and the upper semiconductor layer 170 may be formed as a single or multiple tunnel junction layers, as needed. Accordingly, the uppermost electrodes formed on the respective photo-device portions may have different polarities (n type or p type).

In addition, a buffer layer 20 may be further formed between the substrate 10 and the lower semiconductor layer 110. The buffer layer 20 functions to reduce lattice mismatch between the substrate 10 and the semiconductor layer and may be optionally formed. According to one embodiment of the present invention, the buffer layer 20 may be a single layer containing any one material of GaAs, Un-GaN, AlN, AlGaN, InAlGaN, SiN, MgN, InN, InAs, AlAs, AlGaAs, InAlGaAs, GaP, InGaAsSb, InGaAsP, AlGaAsP, InGaAlAs, GaSb, AlSb, InAs, InSb, AlGaSb, AlInSb, GaInSb, GaInAsSb, or AlGaInSb, or include a plurality of layers including a combination of two or more layers, or a single layer containing two or more materials thereof or include a plurality layers including a combination of two or more layers. The buffer layer 20 may be a single layer depending on the type of the substrate 10 or the lower semiconductor layer 110, or may be a stack of a plurality of the materials. The buffer layer 20 may be formed by a known physical or chemical deposition method.

In addition, the first active layer 120, the second active layer 140 and the third active layer 160 according to one embodiment of the present invention may be formed by repeatedly depositing a plurality of layers containing a combination of two or more of GaN, InGaN, AlGaN, InAlGaN, InAlGaP, GaAs, AlGaAs, InAlGaAs, AlGaASP, InGaAsP, GaP, GaAsP, GaInP, AlGaInP, InGaP, InGaAsSb, InGaAsP, InGaAlAs, GaSb, AlSb, InAs, InSb, AlGaSb, AlInSb, GaInSb, GaInAsSb, or AlGaInSb. Based on the combination of these materials, the active layers may be formed to have the same emission wavelength, or one or a part of the active layers may have a different emission wavelength from remaining active layers.

According to one embodiment of the present invention, in order to form photo-device portions having red (R), green (G), and blue (B) emission wavelengths, at least three active layers having different emission wavelengths are formed. In general, the band gap can be controlled by controlling the elements with which the material is doped. Generally, for red light emission, a non-nitride material such as GaAs is used, and for green light emission, a GaP-based or a non-nitride material or a nitride material with a controlled doping element such as Al or In may be used.

In one embodiment of the present invention, a buffer layer 20 is formed on a substrate 10, and a first active layer 120 having a blue emission wavelength, a second active layer 140 having a green emission wavelength, and a third active layer 160 having a red emission wavelength are formed in that order on the buffer layer 20. Generally, in a device having such a structure, the emission direction is toward the substrate side, and a CMOS backplane, which is a driving substrate of the light-emitting device, is located in the direction opposite to the emission direction.

In addition, according to one embodiment of the present invention, each of the first common semiconductor layer 130 and the second common semiconductor layer 150 includes a tunnel junction layer and is generally formed through junction of a high-concentration p-type semiconductor layer and a high-concentration n-type semiconductor layer. In an embodiment of the present invention, the doping concentration of the tunnel junction layer is about 1×10¹⁸ to 1×10²¹ cm⁻³.

According to one embodiment of the present invention, the tunnel junction layer may have a p/n junction selected from an n⁺⁺-GaN layer, a p⁺⁺-GaN layer, an n⁺⁺-InGaN layer, a p⁺⁺-InGaN layer, an n⁺⁺-AlGaN layer, a p⁺⁺-AlGaN layer, an n⁺⁺-GaAs layer, a p⁺⁺-GaAs layer, an n⁺⁺-InGaAs layer, a p⁺⁺-InGaAs layer, an n⁺⁺-AlGaAs layer, or a p⁺⁺-AlGaAs, and may include a plurality of tunnel junction layers.

In the present invention, the tunnel junction layer is formed with a high-concentration n-type (n⁺⁺) semiconductor layer and a high-concentration p-type (p⁺⁺) semiconductor layer to increase the recombination of electrons and holes in the active layers and is formed with a high-concentration n-type semiconductor layer or a p-type semiconductor layer serving as electrode layers of the photo-device portions. Therefore, the shape and structure of the tunnel junction layer (common semiconductor layer) may be designed in consideration of the arrangement of the electrodes.

The first common semiconductor layer 130 and the second common semiconductor layer 150 may be formed as an n-type semiconductor layers and a p-type semiconductor layer, respectively, on and under the tunnel junction layer, and specific examples of the n-type semiconductor layer and the p-type semiconductor layer are as described above.

In addition, according to one embodiment of the present invention, when the upper semiconductor layer 170 is a p-type semiconductor layer, a diffusion prevention layer or an electron blocking layer is formed between the p-type semiconductor layer and the first active layer 120, and between the p-type semiconductor layer and the second active layer 140, so as to improve electron-hole recombination efficiency. Here, the diffusion prevention layer or the electron blocking layer may be formed using at least one of the p-type semiconductor layer materials.

For example, in an embodiment of the present invention, a buffer layer 20, an n-type lower semiconductor layer 110, a first active layer (blue light-emitting material) 120, a first common semiconductor layer (n⁺⁺-GaN layer/p⁺⁺-GaN layer or n-type semiconductor layer/n⁺⁺-GaN layer/p⁺⁺-GaN layer/p-type semiconductor layer or n-type semiconductor layer/n⁺⁺-GaN layer/p⁺⁺-GaN layer/p-type semiconductor layer/diffusion prevention layer or electron blocking layer) 130 are formed on a substrate to realize a first photo-device layer 210, a second active layer (green light-emitting material) 140, and a second common semiconductor layer (n⁺⁺-GaN layer/p⁺⁺-GaN layer or n-type semiconductor layer/n⁺⁺-GaN layer/p⁺⁺-GaN layer/p-type semiconductor layer or n-type semiconductor layer/n⁺⁺-GaN layer/p⁺⁺-GaN layer/p-type semiconductor layer/diffusion barrier or electron blocking layer) 150 to realize a second photo-device layer 220, and a third active layer (red light-emitting material) 160 and a p-type upper semiconductor layer 170 are formed on the second common semiconductor layer (n⁺⁺-GaN layer/p⁺⁺-GaN layer or n-type semiconductor layer/n⁺⁺-GaN layer/p⁺⁺-GaN layer/p-type semiconductor layer or n-type semiconductor layer/n⁺⁺-GaN layer/p⁺⁺-GaN layer/p-type semiconductor layer/diffusion barrier or electron blocking layer) 150 to realize a third photo-device layer 230. Here, in another embodiment, the p-type and n-type may be switched, and the n-type and p-type are selected in each layer depending on the type of the common electrode (n-type or p-type).

As described above, the second photo-device layer 220 may include a plurality of second photo-device layers 220 which may be formed by repeatedly performing the process of forming an active layer between common semiconductor layers and this improves the uniformity of color distribution and color reproduction upon color mixing or repeated formation of the active layer of the photo-device portion with low luminous efficacy as needed.

Therefore, the intermediate photo-device layers formed according to one embodiment of the present invention share common semiconductor layers interposed therebetween, these layers may serve as n-type semiconductor layers or p-type semiconductor layers for the active layers formed on and under the common semiconductor layers, and thus supply electrons or holes to the active layers, and also may formed as high-concentration n-type semiconductor layers or p-type semiconductor layers and thus serve as electrode layers.

The photo-device layers share common semiconductor layers and the structure of the photo-device and the structure of the electrode realized thereby are appropriately formed and arranged, so that the overall device structure can be compact and a micro- or nano-light-emitting diode suitable for large-area, high-resolution displays can be manufactured.

Parts of the second common semiconductor layer 150, the first common semiconductor layer 130, and the lower semiconductor layer 110 are sequentially opened to form the first photo-device portion 310, the second photo-device portion 320, and the third photo-device portion 330 having the same or different light emitting wavelengths horizontally on the substrate 10 (FIGS. 1B, 1C, and 1D).

According to an embodiment of the present invention, a buffer layer 20, a lower semiconductor layer 110, a first active layer 120 having a blue emission wavelength, a first common semiconductor layer 130, a second active layer 140 having a green emission wavelength, a second common semiconductor layer 150, a third active layer 160 having a red emission wavelength, and an upper semiconductor layer are formed on the substrate 10, and then parts of the second common semiconductor layer 150, the first common semiconductor layer 130, and the lower semiconductor layer 110 are opened to form a photo-device portion including each active layer.

First, a part of the second common semiconductor layer 150 is opened to form a third photo-device portion 330 including an upper semiconductor layer 170, a third active layer 160 having a red emission wavelength, and a second common semiconductor layer 150 (FIG. 1B). In this case, the third photo-device portion 330 is formed by masking the third photo-device portion area and etching the remaining area such that a part of the second common semiconductor layer 150 is opened. The open area of the second common semiconductor layer 150 can be controlled by adjusting the masking area as needed.

In addition, a part of the first common semiconductor layer 130 is opened to form a second photo-device portion 320 including a second common semiconductor layer 150, a second active layer 140 having a green emission wavelength, and a first common semiconductor layer 130 (FIG. 1C). The second photo-device portion 320 is formed by masking areas of the third photo-device portion 330 and the second photo-device portion 320 and etching the remaining area such that a part of the first common semiconductor layer 130 is opened. The open area of the first common semiconductor layer 130 can be controlled by adjusting the masking area as needed.

In addition, a part of the lower semiconductor layer 110 is opened to form a first photo-device portion 310 including a first common semiconductor layer 130, a first active layer 120 having a blue emission wavelength, and a lower semiconductor layer 110 (FIG. 1D). The first photo-device portion 310 is formed by masking areas of the first photo-device portion 310, the second photo-device portion 320, and the third photo-device portion 330, and etching the remaining areas such that that a part of the lower semiconductor layer 110 is opened.

Here, the number of photo-device portions can be controlled in the horizontal direction by controlling the masking area and the open area of each semiconductor layer as needed. That is, combinations of RRGB, RRGGB, and RGGB as needed enable light emission and the photo-device portions with low light emission efficiency are reinforced depending on the heights or positions of the materials or the devices to ensure uniformity of color distribution and color reproduction.

At this time, the first photo-device portion 310, the second photo-device portion 320, and the third photo-device portion 330 may be completely separated except for the substrate 10, and this can be realized by an isolation process, or the like. This allows each photo-device portion to operate independently and the photo-device portions are formed in the horizontal direction on the substrate 10, so that RGB pixels can be implemented by independent operation without color mixing between the photo-device portions.

In addition, the second photo-device portion 320 and the third photo-device portion 330 formed horizontally on the substrate 10 may horizontally share at least one of the first common semiconductor layer 130 or the second common semiconductor layer 150 and may be formed to operate independently from or in conjunction with each other. A variety of photo-device portions that simultaneously emit light, such as RG, RGB, and GB, may be used as needed.

In addition, a current spreading layer 410 may be optionally formed on each photo-device portion or an activation process may be optionally performed to further increase luminous efficacy (FIG. 1E). The activation process may be performed by heat treatment in a range of 200° C. to 900° C. for 30 seconds to 2 hours, and may be performed in an atmosphere of at least one of air, O₂, N₂, and Ar, or under vacuum. In addition, before forming the current spreading layer 410, the heat treatment may be performed at 200° C. to 900° C. for 30 seconds to 2 hours, and the activation process may be performed in an atmosphere of at least one of air, O₂, N₂, and Ar, or under vacuum, the current spreading layer 410 may be formed, and the heat treatment process may be repeated.

In addition, a first electrode 510 is formed on the lower semiconductor layer 110, and a second electrode 520 is formed on each of the first photo-device portion 310, the second photo-device portion 320, and the third photo-device portion 330, or a first electrode 510 is formed on one region of the open lower semiconductor layer 110, the first common semiconductor layer 130, and the second common semiconductor layer 150, and a second electrode 520 is formed on each of the first photo-device portion 310, the second photo-device portion 320, and the third photo-device portion 330 (FIG. 1F).

In addition, the first electrode 510 is formed in a controlled open area of the second common semiconductor layer 150 and the first common semiconductor layer 130 such that each of the second common semiconductor layer 150 and the first common semiconductor layer 130 can serve as the first electrode 510 (e.g., n-type electrode) of the third photo-device portion 330 and the second photo-device portion 320. Here, the second common semiconductor layer 150 and the first common semiconductor layer 130 connected to the first electrode 510 may be formed as n⁺⁺ semiconductor layers (e.g., n⁺⁺-GaN layer) doped at a high concentration in the tunnel junction layer and may serve as electrode layers.

The tunnel junction layer supplies electrons and holes on or under the active layers as described above, and is doped at a high concentration and also serves as an electrode layer of the photo-device portion formed thereon.

In addition, the second common semiconductor layer 150 and the first common semiconductor layer 130 may be formed in any one open shape of a polygon, a circle, an ellipse, or a bridge, but is not limited thereto.

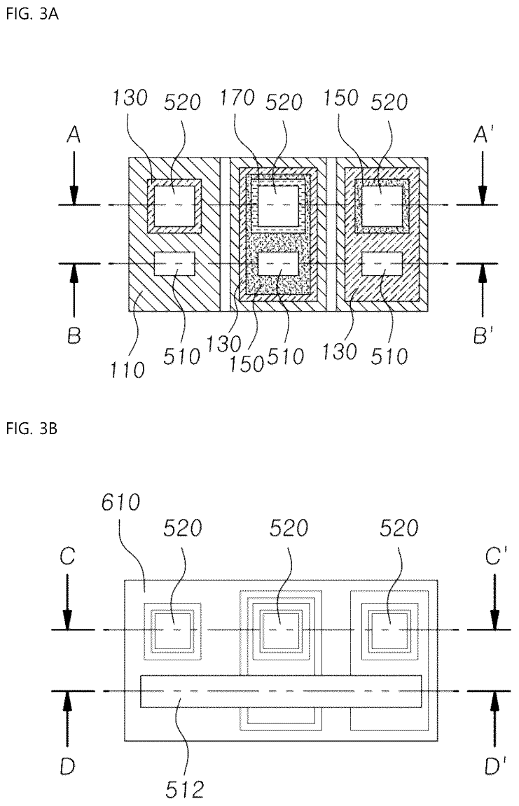

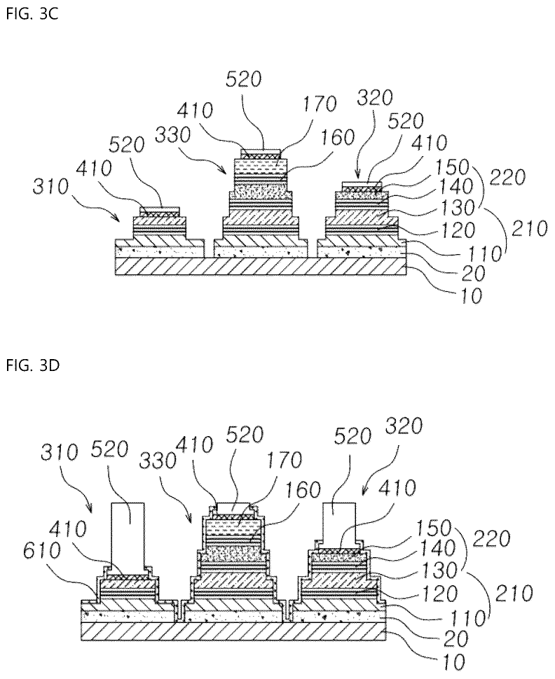

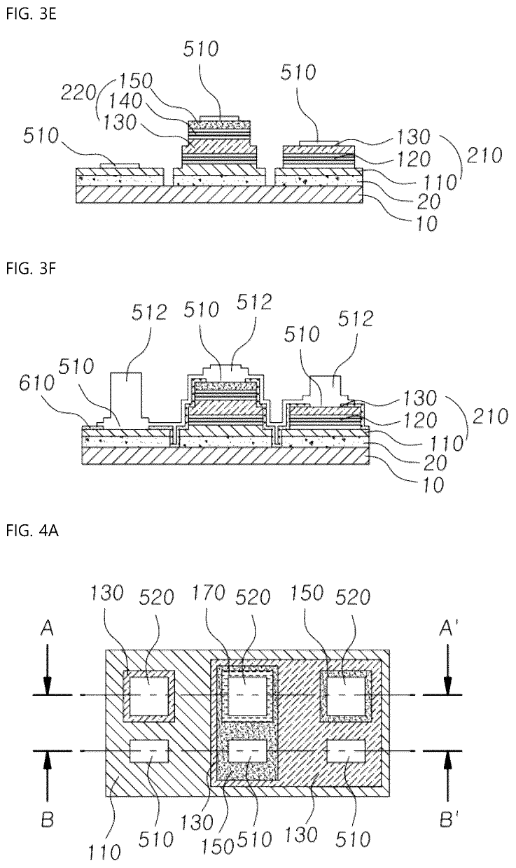

In one embodiment of the present invention, the open area of the second common semiconductor layer 150 and the first common semiconductor layer 130 is formed as a square (see FIGS. 3A, 3B, 3C, 3D, 3E and 3F, FIGS. 4A, 4B, 4C, 4D, 4E and 4F, FIGS. 5A, 5B, 5C and 5D, FIGS. 6A, 6B, 6C and 6D, and FIGS. 7A, 7B, 7C, 7D, 7E and 7F) or a bridge shape (see FIGS. 2A, 2B, 2C, 2D, 2E and 2F), the second electrode 520 is formed in each photo-device portion area, and the first electrode 510 is formed in the open area to realize the photo-device portion.

Here, the first electrode 510 formed on the second common semiconductor layer 150, the first common semiconductor layer 130, and the lower semiconductor layer 110 may be arranged on the same line and connected to each other to form a common electrode 512 (see FIGS. 2A, 2B, 2C, 2D, 2E and 2F, FIGS. 3A, 3B, 3C, 3D, 3E and 3F, FIGS. 4A, 4B, 4C, 4D, 4E and 4F, FIGS. 5A, 5B, 5C and 5D, and FIGS. 7A, 7B, 7C, 7D, 7E and 7F).

In addition, the first electrode 510 may be formed in any one of polygonal, circular, oval, and bridge shapes depending on the shape and structure of the photo-device portion, and the ends of the first electrode 510 may be designed to be arranged on the same line to form a common electrode 512. In one embodiment of the present invention, the first electrode 510 is formed in a square or bridge shape.

In addition, after the formation of the first electrode 510 and the second electrode 520, a passivation film 610 that opens the electrode area may be formed over the entire photoelectronic device, or a passivation film 610 may be first formed over the entire photoelectronic device, a part of the passivation film 610 may be opened, and the first electrode 510 and the second electrode 520 may be formed in the opened area (FIG. 1G).

Here, the passivation film 610 is formed to a thickness of 25 nm to 2 μm using at least one material of SiO₂, SiOₓ, SiNₓ, Si₃N₄, Al₂O₃, AlN, BN, TaN, TiN, ZrN, WN, VN, NbN, YN, or HfN.

After the formation of the passivation film 610, the first electrode 510 and the second electrode 520, the first electrode 510 formed on the lower semiconductor layer 110 and the first electrode 510 formed on one area of the first common semiconductor layer 130 and the second common semiconductor layer 150 may be connected to each other to form a common electrode 512 (FIG. 1H). As described above, the common semiconductor layer and the first electrode 510 may be designed in a bridge shape to provide easy connection to the common electrode.

In addition, the first electrode 510 and the second electrode 520 may be formed to be flush with each other by adjusting the heights of the first electrode 510 and the second electrode 520. This enables easy connection of the photoelectronic device to a PCB or CMOS backplane.

The photoelectronic device according to the present invention has an optimal structure that improves the spatial arrangement efficiency of electrodes and further increases luminous efficacy by designing the shape and structure of photo-device portions and controlling open areas.

Hereinafter, various embodiments of the present invention will be described in more detail with reference to the attached drawings.

### First Embodiment

As shown in FIGS. 2A, 2B, 2C, 2D, 2E and 2F, according to a first embodiment of the present invention, a buffer layer 20 is formed on a substrate 10, and a first photo-device portion 310 for emitting blue light, a second photo-device portion 320 for emitting green light, and a third photo-device portion 330 for emitting red light are formed on the buffer layer 20 in a horizontal direction based on the substrate 10.

In the epitaxial structure of the buffer layer and the photo-device layer that are stacked in a vertical direction, an area of the third photo-device portion is masked and the remaining area is etched such that a part of the second common semiconductor layer 150 is opened, to form the third photo-device portion 330.

Then, the third photo-device portion area and the second photo-device portion area are masked, the remaining area is etched, the second common semiconductor layer 150 is etched in a bridge shape, and the first common semiconductor layer 130 is opened, so that the second photo-device portion 320 is formed in the bridge of the second common semiconductor layer 150 that has been etched in the bridge shape.

Then, the third photo-device portion area, the second photo-device portion area and the first photo-device portion area are masked, the remaining area is etched, the first common semiconductor layer 130 is etched in a bridge shape, and the lower semiconductor layer 110 is opened, so that the first photo-device portion 310 is formed in the bridge of the first common semiconductor layer 130 that has been etched in the bridge shape.

In this embodiment, a second electrode 520 is formed on each photo-device portion. In this case, the bridge of the second common semiconductor layer 150 and the bridge of the first common semiconductor layer 130 extend horizontally on the substrate 10, and the first electrode 510 is formed on the lower semiconductor layer 110 that is open between one side of each bridge and the bridge. As a result, the first electrode 510 is arranged on the same line on one side of the photoelectronic device, thus enabling easy formation of the common electrode 512 and efficient spatial arrangement of the electrodes.

The common electrode 512 is preferably formed after the passivation film 610 that opens an electrode area is formed over the entire area of the photoelectronic device. In addition, in some cases, before formation of the electrode, the passivation film 610 may be formed and the electrode may be formed in the open electrode area and then may be connected to the common electrode.

FIG. 2A is a planar schematic diagram illustrating the shape and structure of each photo-device portion and the arrangement of electrodes, and illustrates the configuration in which the second electrode 520 is formed in each photo-device portion, the first electrode 510 of the third photo-device portion 330 is formed on the bridge of the second common semiconductor layer 150, the first electrode 510 of the second photo-device portion 320 is formed on the bridge of the first common semiconductor layer 130, and the first electrode 510 of the first photo-device portion 310 is formed on the lower semiconductor layer 110. FIG. 2C is a cross-sectional schematic diagram taken along line A-A′ of FIG. 2A, and FIG. 2E is a cross-sectional schematic diagram taken along line B-B′ of FIG. 2A.

FIG. 2B is a planar schematic diagram illustrating the formation of the passivation film 610 and a common electrode 512 for the first electrode 510, FIG. 2D is a cross-sectional schematic diagram taken along line C-C′, and FIG. 2F is a cross-sectional schematic diagram taken along line D-D′.

As such, the photo-device portions are horizontally arranged on the substrate 10, the photo-device layers vertically share the common semiconductor layer, and the third photo-device portion 330 and the second photo-device portion 320 horizontally share the first common semiconductor layer 130, thereby providing a photoelectronic device that has a compact structure due to easy formation of a common electrode, minimizes color mixing problems, and exhibits excellent electrical characteristics due to reduced problems of high driving voltage and current leakage.

In addition, the common semiconductor layer is formed in a bridge shape and the first electrode 510 is arranged on one side such that the first electrode 510 can be easily connected to the common electrode 512, thereby improving the efficiency of the spatial arrangement of the electrodes, and enabling miniaturization of RGB pixels and application to large-area, high-resolution full-color displays.

### Second Embodiment

As shown in FIGS. 3A, 3B, 3C, 3D, 3E and 3F, according to the second embodiment of the present invention, a buffer layer 20 is formed on a substrate 10, and a first photo-device portion 310 for emitting blue light, a second photo-device portion 320 for emitting green light, and a third photo-device portion 330 for emitting red light are formed on the buffer layer 20 in a horizontal direction based on the substrate 10. Similar to the first embodiment, each photo-device portion is formed in an open area determined by masking and etching. In particular, in this embodiment, each photo-device portion can be completely isolated except for the substrate 10 and this configuration can be formed by an isolation process, or the like.

In this embodiment, the open areas of the first common semiconductor layer 130 and the second common semiconductor layer 150 are formed in a square shape. As a result, the open area of the lower semiconductor layer 110 is also formed in a square shape. In this embodiment, the open areas of the first common semiconductor layer 130, the second common semiconductor layer 150 and the lower semiconductor layer 110 form a square shape extending in a direction vertical to the arrangement direction of the photo-device portions.

By forming the second electrode 520 on each photo-device portion and forming the first electrode 510 in the extended areas on the second common semiconductor layer 150, the first common semiconductor layer 130, and the lower semiconductor layer 110 that are opened in the square shape, the first electrode 510 is arranged on one side of the RGB pixel, the formation of the common electrode 512 is easy and the spatial arrangement of the electrodes is efficiently performed.

FIG. 3A is a planar schematic diagram illustrating the shape and structure of each photo-device portion and the arrangement of electrodes, and illustrates the configuration in which the second electrode 520 is formed in each photo-device portion, the first electrode 510 of the third photo-device portion 330 is formed on the second common semiconductor layer 150, the first electrode 510 of the second photo-device portion 320 is formed on the first common semiconductor layer 130, and the first electrode 510 of the first photo-device portion 310 is formed on the lower semiconductor layer 110. FIG. 3C is a cross-sectional schematic diagram taken along line A-A′ of FIG. 3A, and FIG. 3E is a cross-sectional schematic diagram taken along line B-B′ of FIG. 3A.

FIG. 3B is a planar schematic diagram illustrating the formation of the passivation film 610 and a common electrode for the first electrode 510, FIG. 3D is a cross-sectional schematic diagram taken along line C-C′, and FIG. 3F is a cross-sectional schematic diagram taken along line D-D′.

FIG. 3F illustrates a structure in which the first electrode 510 and the second electrode 520 are formed to be flush with each other by adjusting the heights of the first electrode 510 and the second electrode 520, thereby providing easy bonding with a PCB or CMOS backplane.

As such, the third photo-device portion 330 and the second photo-device portion 320 are formed such that the photo-device portions are horizontally arranged on the substrate 10 and the photo-device layers vertically share the common semiconductor layer, thereby providing a photoelectronic device that has a compact structure due to formation of a common electrode, minimizes color mixing problems, and exhibits excellent electrical characteristics due to reduced problems of high driving voltage and current leakage.

In addition, the photo-device portion is formed in a square shape and the first electrode 510 is arranged on one side thereof such that the first electrode 510 can be easily connected to the common electrode 512, thereby improving the efficiency of the spatial arrangement of the electrodes, and enabling miniaturization of RGB pixels and application to large-area, high-resolution full-color displays.

### Third Embodiment

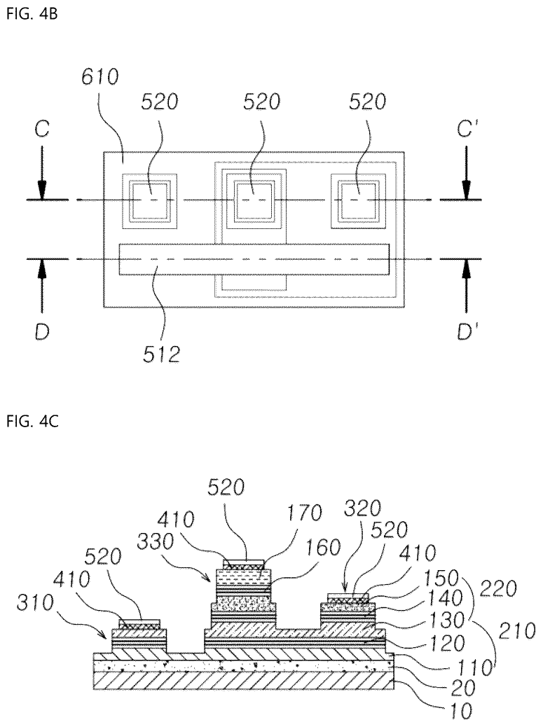

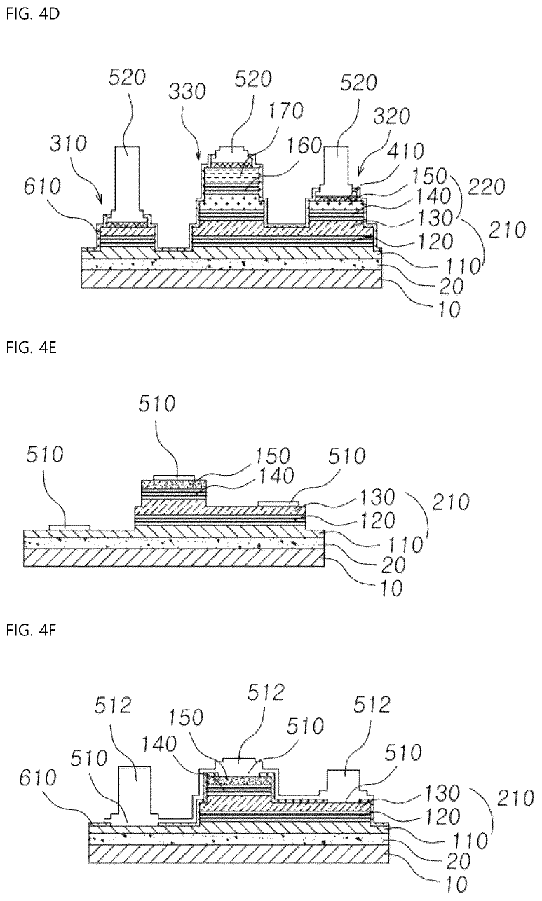

As shown in FIGS. 4A, 4B, 4C, 4D, 4E and 4F, according to a third embodiment of the present invention, a buffer layer 20 is formed on a substrate 10, and a first photo-device portion 310 for emitting blue light, a second photo-device portion 320 for emitting green light, and a third photo-device portion 330 for emitting red light are formed on the buffer layer 20 in a horizontal direction based on the substrate 10. Similar to the first embodiment and the second embodiment, each photo-device portion is formed in an open area determined by masking and etching.

In particular, in this embodiment, the second photo-device portion 320 and the third photo-device portion 330 horizontally share the first common semiconductor layer 130, and the open areas of the first common semiconductor layer 130, the second common semiconductor layer 150, and the lower semiconductor layer 110 form a square shape extending in the direction vertical to the arrangement direction of the photo-device portions.

In this embodiment, the open areas of the first common semiconductor layer 130 and the second common semiconductor layer 150 are formed in a square shape. As a result, the open area of the lower semiconductor layer 110 is also formed in a square shape.

By forming the second electrode 520 on each photo-device portion and forming the first electrode 510 on the second common semiconductor layer 150, the first common semiconductor layer 130 and the lower semiconductor layer 110 in an open area that extends in a direction vertical to the arrangement direction of the photo-device portion, the first electrode 510 is arranged on one side of the RGB pixel, the formation of the common electrode 512 is easy and the spatial arrangement of the electrodes is efficiently performed.

FIG. 4A is a planar schematic diagram illustrating the shape and structure of each photo-device portion and the arrangement of electrodes, and illustrates the configuration in which the second electrode 520 is formed in each photo-device portion, the first electrode 510 of the third photo-device portion 330 is formed on the second common semiconductor layer 150, the first electrode 510 of the second photo-device portion 320 is formed on the first common semiconductor layer 130, and the first electrode 510 of the first photo-device portion 310 is formed on the lower semiconductor layer 110. FIG. 4C is a cross-sectional schematic diagram taken along line A-A′ of FIG. 4A, and FIG. 4E is a cross-sectional schematic diagram taken along line B-B′ of FIG. 4A.

FIG. 4B is a planar schematic diagram illustrating the formation of the passivation film 610 and a common electrode for the first electrode 510, FIG. 4D is a cross-sectional schematic diagram taken along line C-C′, and FIG. 4F is a cross-sectional schematic diagram taken along line D-D′.

FIG. 4F illustrates a structure in which the first electrode 510 and the second electrode 520 are formed to be flush with each other by adjusting the heights of the first electrode 510 and the second electrode 520, thereby providing easy bonding with a PCB or CMOS backplane.

As such, the photo-device portions are horizontally arranged on the substrate 10, the photo-device layers vertically share the common semiconductor layer, and the third photo-device portion 330 and the second photo-device portion 320 horizontally share the first common semiconductor layer 130, thereby providing a photoelectronic device that has a compact structure, minimizes color mixing problems, and exhibits excellent electrical characteristics due to reduced problems of high driving voltage and current leakage.

In addition, the photo-device portion is formed in a square shape and the first electrode 510 is arranged on one side thereof such that the first electrode 510 can be easily connected to the common electrode 512, thereby improving the efficiency of the spatial arrangement of the electrodes, and enabling miniaturization of RGB pixels and application to large-area, high-resolution full-color displays.

### Fourth Embodiment

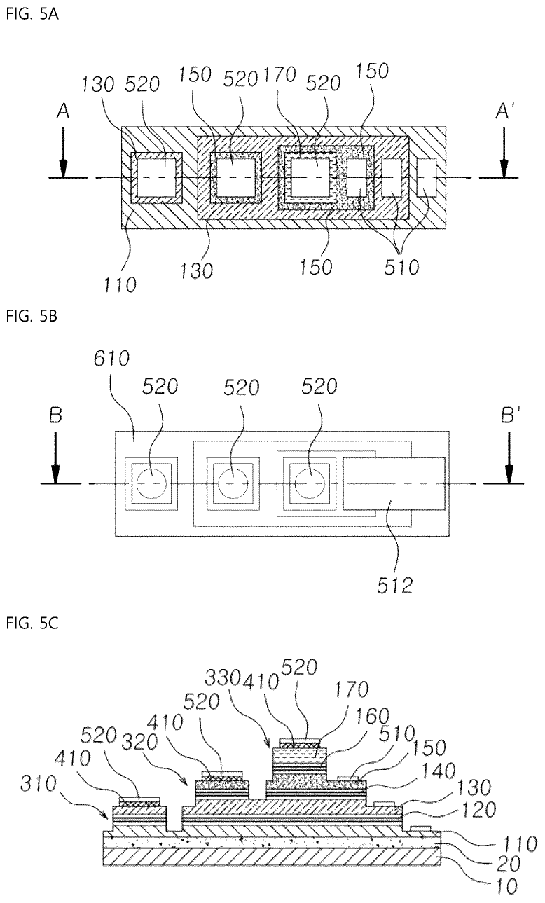

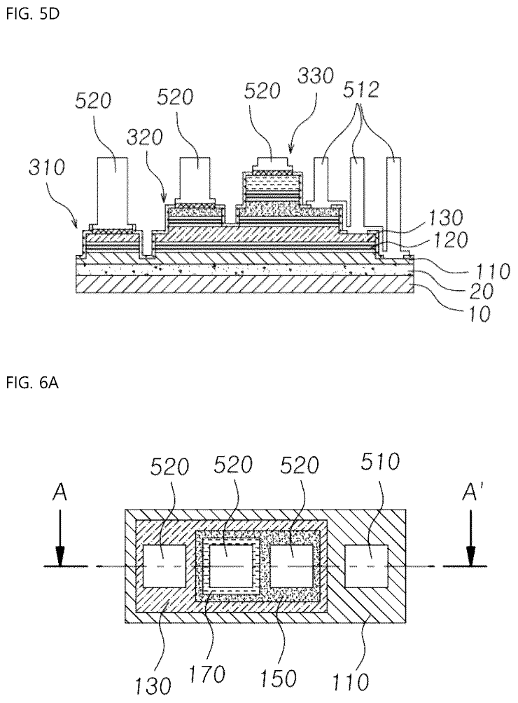

As shown in FIGS. 5A, 5B, 5C and 5D, according to a fourth embodiment of the present invention, a buffer layer 20 is formed on a substrate 10, and a first photo-device portion 310 for emitting blue light, a second photo-device portion 320 for emitting green light, and a third photo-device portion 330 for emitting red light are formed on the buffer layer 20 in a horizontal direction based on the substrate 10. Similar to the first embodiment and the second embodiment, each photo-device portion is formed in an open area determined by masking and etching.

In particular, in this embodiment, the second photo-device portion 320 and the third photo-device portion 330 horizontally share the first common semiconductor layer 130, and the open areas of the first common semiconductor layer 130, the second common semiconductor layer 150, and the lower semiconductor layer 110 form a square shape extending in the direction parallel to the arrangement direction of the photo-device portions.

In this embodiment, the open areas of the first common semiconductor layer 130 and the second common semiconductor layer 150 are formed in a square shape. As a result, the open area of the lower semiconductor layer 110 is also formed in a square shape.

By forming the second electrode 520 on each photo-device portion and forming the first electrode 510 on the second common semiconductor layer 150, the first common semiconductor layer 130 and the lower semiconductor layer 110 in an open area that extends in the arrangement direction of the photo-device portion, the first electrode 510 is arranged on one side of the RGB pixel, the formation of the common electrode 512 is easy and the spatial arrangement of the electrodes is efficiently performed.

FIG. 5A is a planar schematic diagram illustrating the shape and structure of each photo-device portion and the arrangement of electrodes, and illustrates the configuration in which the second electrode 520 is formed in each photo-device portion, the first electrode 510 of the third photo-device portion 330 is formed on the second common semiconductor layer 150, the first electrode 510 of the second photo-device portion 320 is formed on the first common semiconductor layer 130, and the first electrode 510 of the first photo-device portion 310 is formed on the lower semiconductor layer 110. FIG. 5C is a cross-sectional schematic diagram taken along the line A-A′ of FIG. 5A.

FIG. 5B is a planar schematic diagram illustrating the formation of the passivation film 610 and a common electrode for the first electrode 510, and FIG. 5D is a cross-sectional schematic diagram taken along the line B-B′ and illustrates a structure in which the first electrode 510 and the second electrode 520 are formed to be flush with each other by adjusting the heights of the first electrode 510 and the second electrode 520, thereby providing easy bonding with a PCB or CMOS backplane.

As such, the photo-device portions are horizontally arranged on the substrate 10, the photo-device layers vertically share the common semiconductor layer, and the third photo-device portion 330 and the second photo-device portion 320 horizontally share the first common semiconductor layer 130, thereby providing a photoelectronic device that has a compact structure, minimizes color mixing problems, and exhibits excellent electrical characteristics due to reduced problems of high driving voltage and current leakage.

In addition, the photo-device portion is formed in a square shape and the first electrode 510 is arranged on one side thereof such that the first electrode 510 can be easily connected to the common electrode 512, thereby improving the efficiency of the spatial arrangement of the electrodes, and enabling miniaturization of RGB pixels and application to large-area, high-resolution full-color displays.

### Fifth Embodiment

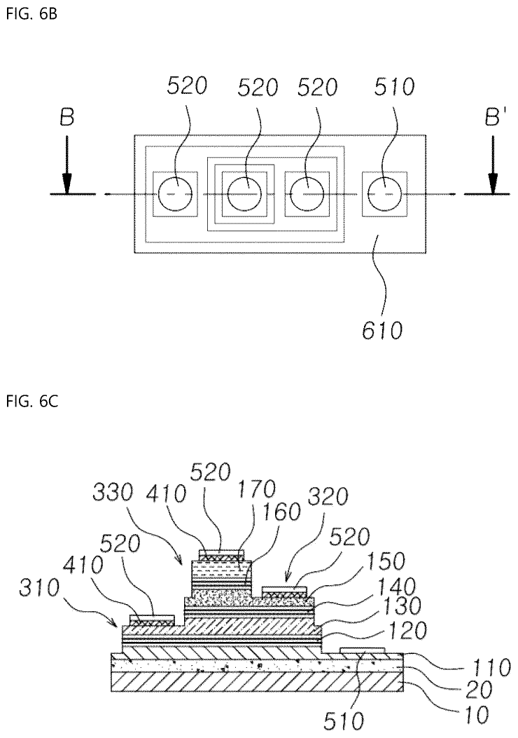

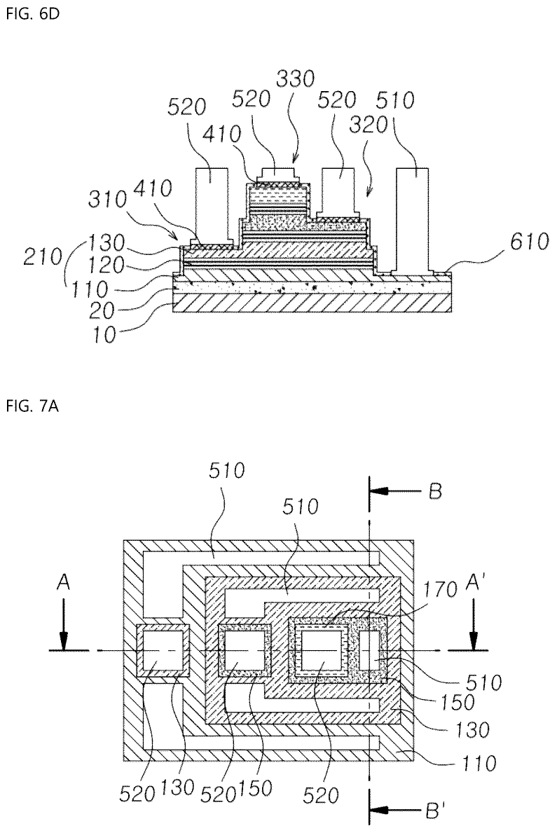

As shown in FIGS. 6A, 6B, 6C and 6D, according to a fifth embodiment of the present invention, a buffer layer 20 is formed on a substrate 10, and a first photo-device portion 310 for emitting blue light, a second photo-device portion 320 for emitting green light, and a third photo-device portion 330 for emitting red light are formed on the buffer layer 20 in a horizontal direction based on the substrate 10. Similar to the first embodiment and the second embodiment, each photo-device portion is formed in an open area determined by masking and etching.

In particular, in this embodiment, the second photo-device portion 320 and the third photo-device portion 330 horizontally share the first common semiconductor layer 130 and the second common semiconductor layer 150, the second photo-device portion 320 and the first photo-device portion 310 share the first common semiconductor layer 130, and the first electrode 510 is formed on the lower semiconductor layer that is open parallel to the arrangement direction of the photo-device portion. In this embodiment, the first electrode 510 becomes the common electrode 512.

In this embodiment, the open areas of the first common semiconductor layer 130 and the second common semiconductor layer 150 are formed in a square shape. As a result, the open area of the lower semiconductor layer 110 is also formed in a square shape.

A second electrode 520 is formed on each photo-device portion and a first electrode 510 is formed on a lower semiconductor layer that is open parallel to the arrangement direction of the photo-device portion.

FIG. 6A is a planar schematic diagram illustrating the shape and structure of each photo-device portion and the arrangement of electrodes, and illustrates the configuration in which the second electrode 520 is formed in each photo-device portion, and the first electrode 510 of the third photo-device portion 330 is formed on the lower semiconductor layer 110. FIG. 6C is a cross-sectional schematic diagram taken along the line A-A′ of FIG. 6A.

FIG. 6B is a planar schematic diagram illustrating the formation of the passivation film 610 and a common electrode 512 for the first electrode 510, and FIG. 6D is a cross-sectional schematic diagram taken along the line B-B′ and illustrates a structure in which the first electrode 510 and the second electrode 520 are formed to be flush with each other by adjusting the heights of the first electrode 510 and the second electrode 520, thereby providing easy bonding with a PCB or CMOS backplane.

As such, the photo-device portions are horizontally arranged on the substrate 10, the photo-device layers vertically share the common semiconductor layer, the second photo-device portion 320 and the third photo-device portion 330 horizontally share the first common semiconductor layer 130 and the second common semiconductor layer 150, and the second photo-device portion 320 and the first photo-device portion 310 horizontally share the first common semiconductor layer 130, thereby providing a photoelectronic device that has a compact structure, minimizes color mixing problems, and exhibits excellent electrical characteristics due to reduced problems of high driving voltage and current leakage.

In addition, the photo-device portion is formed in a square shape and the first electrode 510 is arranged on one side thereof such that the first electrode 510 can be easily connected to the common electrode 512, thereby improving the efficiency of the spatial arrangement of the electrodes, and enabling miniaturization of RGB pixels and application to large-area, high-resolution full-color displays.

In addition, in this embodiment, the second photo-device portion 320 and the third photo-device portion 330 horizontally share the first common semiconductor layer 130 and the second common semiconductor layer 150 such that the photo-device portions may operate independently from or in conjunction with each other. As a result, the area of the photo-device portion that has low luminous efficacy or is located far from the luminous surface is increased, as needed, the photo-device portion with low luminous efficacy can be reinforced, and the uniformity of color distribution and color reproduction can thus be improved. For example, in the embodiment of the present invention, the area of the green light-emitting photo-device portion with low luminous efficacy is wide, thereby providing the effect of forming RGGB, RGBBB, and RGGBBB pixels.

That is, in the fifth embodiment, the photo-device portions horizontally share the common semiconductor layers and the active layers, so that the active layer of the third photo-device portion 330 is limited to the third photo-device portion area and light emission occurs in the third photo-device portion area, the active layer of the second photo-device portion 320 extends to the third photo-device portion area and light emission occurs in the third photo-device portion area and the second photo-device portion area, and the active layer of the first photo-device portion 310 extends to the second photo-device portion area and the third photo-device portion area and light emission occurs in all of the third photo-device portion area, the second photo-device portion area and the first photo-device portion area.

As such, the present invention has the advantage of easy expansion of the light-emitting region based on the structure in which the respective photo-device portions horizontally share the common semiconductor layers and the active layers.

### Sixth Embodiment

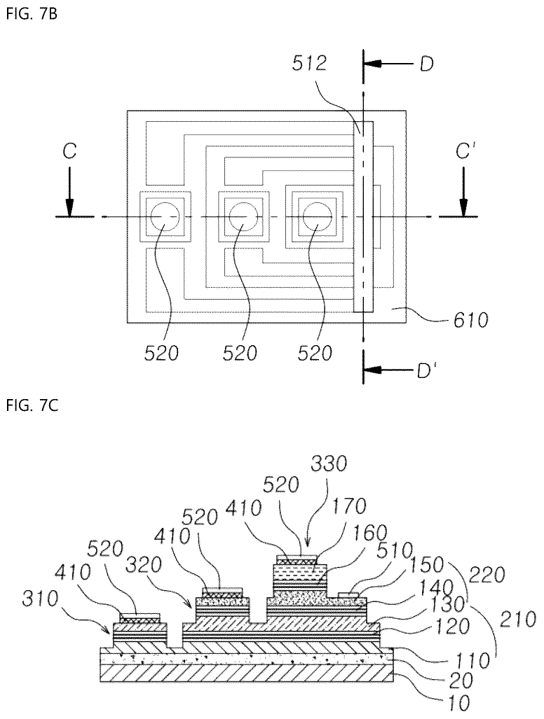

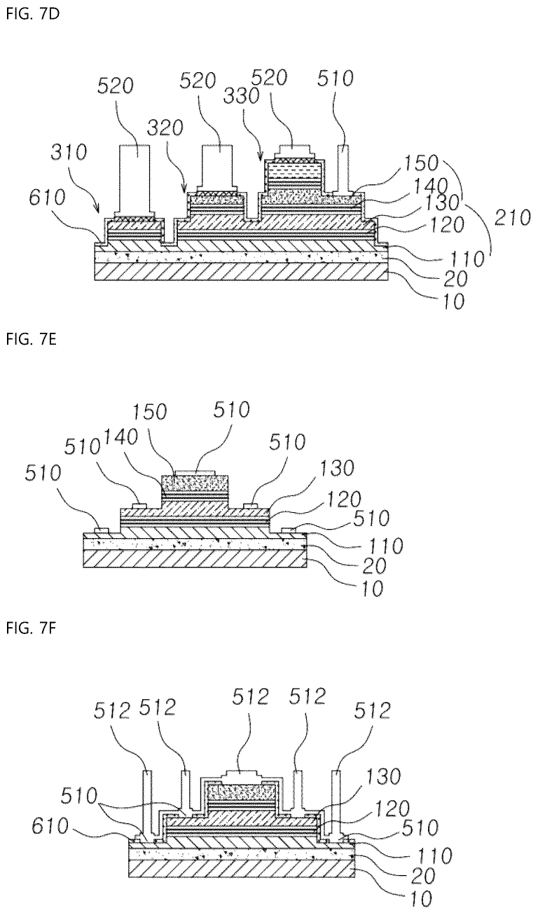

As shown in FIGS. 7A, 7B, 7C, 7D, 7E and 7F, according to a sixth embodiment of the present invention, a buffer layer 20 is formed on a substrate 10, and a first photo-device portion 310 for emitting blue light, a second photo-device portion 320 for emitting green light, and a third photo-device portion 330 for emitting red light are formed on the buffer layer 20 in a horizontal direction based on the substrate 10. Similar to the first embodiment and the second embodiment, each photo-device portion is formed in an open area determined by masking and etching.

In particular, in this embodiment, the second photo-device portion 320 and the third photo-device portion 330 horizontally share the first common semiconductor layer 130 and the open area of the second common semiconductor layer 150 forms a square shape that extends in a direction parallel to the arrangement direction of the photo-device portion, and the open area of the first common semiconductor layer 130 forms a square shape that extends to both sides of the photo-device portion in a direction vertical to the arrangement direction of the photo-device portion.

In this embodiment, the open areas of the first common semiconductor layer 130 and the second common semiconductor layer 150 are formed in a square shape. As a result, the open area of the lower semiconductor layer 110 is also formed in a square shape.

A second electrode 520 is formed on each photo-device portion, a first electrode 510 is formed on a second common semiconductor layer 150 in an open area extending in a direction parallel to the arrangement direction of the photo-device portion, a first electrode 510 is formed in a bridge shape on a first common semiconductor layer 130 on an open area extending on both sides of the photo-device portion in a direction vertical to the arrangement direction of the photo-device portion, and the first electrode 510 of the first photo-device portion 310 on the lower semiconductor layer is also formed in a bridge shape outside at a position adjacent to the first photo-device portion 310.

Accordingly, the first electrode 510 of the third photo-device portion 330, the bridge-type first electrode 510 of the second photo-device portion 320, and the bridge-type first electrode 510 of the first photo-device portion 310 are arranged such that one end thereof is placed on one side of the device and a common electrode 512 is formed, thereby ensuring efficient spatial arrangement of the electrodes.

FIG. 7A is a planar schematic diagram illustrating the shape and structure of each photo-device portion and the arrangement of electrodes, and illustrates the configuration in which the second electrode 520 is formed in each photo-device portion, the first electrode 510 of the third photo-device portion 330 is formed the second common semiconductor layer 150, the first electrode 510 of the second photo-device portion 320 is formed in a bridge shape on the first common semiconductor layer 130, and the first electrode 510 of the first photo-device portion 310 is formed in a bridge shape on the lower semiconductor layer 110.

FIG. 7C is a cross-sectional schematic diagram taken along line A-A′ of FIG. 7A and FIG. 7E is a cross-sectional schematic diagram taken along line B-B′ of FIG. 7A.

FIG. 7B is a planar schematic diagram illustrating the formation of the passivation film 610 and a common electrode 512 for the first electrode 510, FIG. 7D is a cross-sectional schematic diagram taken along line C-C′ and FIG. 7D is a cross-sectional schematic diagram taken along line D-D′. FIG. 7F illustrates a structure in which the first electrode 510 and the second electrode 520 are formed to be flush with each other by adjusting the heights of the first electrode 510 and the second electrode 520, thereby providing easy bonding with a PCB or CMOS backplane.

As such, the photo-device portions are horizontally arranged on the substrate 10, the photo-device layers vertically share the common semiconductor layer, and the second photo-device portion 320 and the third photo-device portion 330 horizontally share the first common semiconductor layer 130, thereby providing a photoelectronic device that has a compact structure, minimizes color mixing problems, and exhibits excellent electrical characteristics due to reduced problems of high driving voltage and current leakage.

In addition, the photo-device portion is formed in a square shape and the electrode is arranged on one side in a bridge shape and square shape to provide easy connection of the first electrode 510 to the common electrode 512, thereby improving the efficiency of the spatial arrangement of the electrodes, and enabling miniaturization of RGB pixels and application to large-area, high-resolution full-color displays.

In addition, by forming the bridge-type first electrode 510, the area of the electrode is increased, the spreading effect of carriers (e.g., electrons) is improved, and luminous efficacy can be further improved.

Actual implementation examples of photovoltaic devices according to embodiments of the present invention are shown as follows. Materials used in specific embodiments of the present invention are as follows:
p-GaN (upper semiconductor layer)/active layer having red emission wavelength (third active layer)/n⁺⁺-GaN layer/p⁺⁺-GaN (second common semiconductor layer, n-electrode for red photo-device portion and p-electrode for green photo-device portion)/active layer having green emission wavelength (second active layer)/n⁺⁺-GaN layer/p⁺⁺-GaN (first common semiconductor layer, n-electrode for green photo-device portion and p-electrode for blue photo-device portion)/active layer having blue emission wavelength (first active layer)/n-GaN (lower semiconductor layer)/buffer layer/substrate

FIGS. 8A, 8B, 8C, 8D and 8E are images showing an actual implementation example of the photoelectronic device according to the second embodiment. FIG. 8A is a schematic diagram illustrating the formation of connection electrodes to the first electrode 510 and the second electrode 520 to drive the photoelectronic device according to the second embodiment, and FIG. 8B illustrates a photoelectronic device with multiple wavelengths actually manufactured in accordance with FIG. 8A.

As shown in FIG. 8B, when a (+) voltage is applied to the \textcircled{2} electrode of FIG. 8A and a (−) voltage is applied to the \textcircled{4} electrode, red light is emitted (FIG. 8C), and when a (+) voltage is applied to the \textcircled{3} electrode of FIG. 8A and a (−) voltage is applied to the \textcircled{4} electrode, green light is emitted (FIG. 8D). In addition, when a (+) voltage is applied to the \textcircled{1} electrode of FIG. 8A and a (−) voltage is applied to the \textcircled{4} electrode, blue light is emitted (FIG. 8E).

That is, according to an embodiment of the present invention, red, green and blue light are independently emitted using four electrodes (electrodes \textcircled{1}, \textcircled{2}, \textcircled{3} and \textcircled{4}), thereby providing a photoelectronic device with multiple wavelengths that minimizes the problem of color mixing, exhibits excellent electrical characteristics based on reduced problems of high driving voltage and leakage current, and realizes full-color RGB pixels.

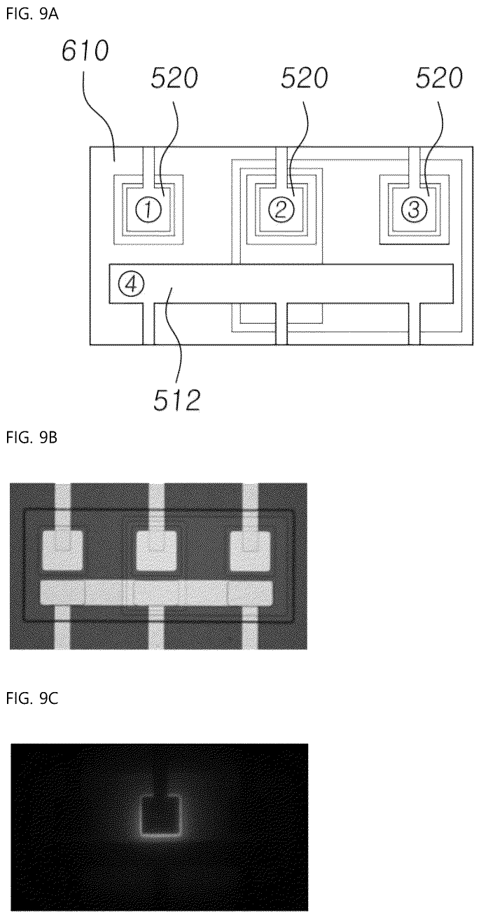

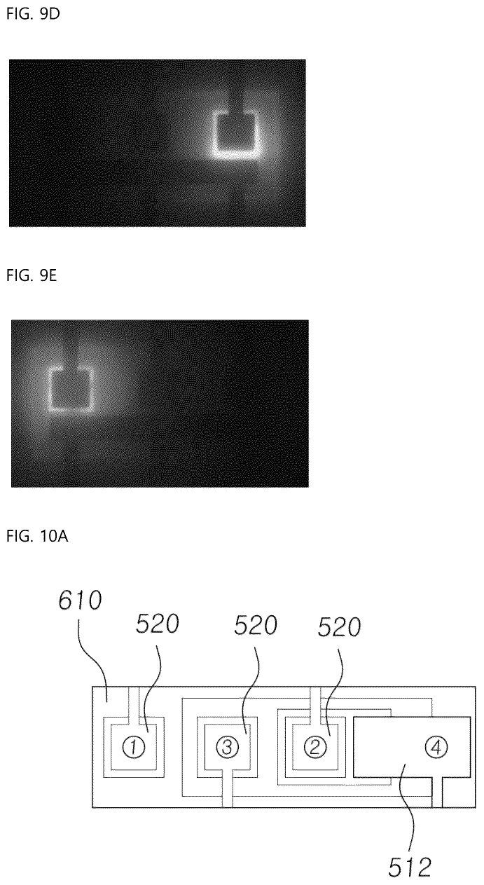

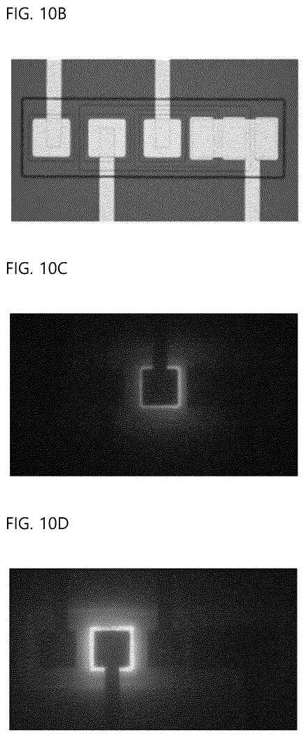

FIGS. 9A, 9B, 9C, 9D and 9E are images showing an actual implementation example of a photoelectronic device according to the third embodiment. FIG. 9A is a schematic diagram illustrating the formation of connection electrodes to the first electrode 510 and the second electrode 520 to drive the photoelectronic device according to the third embodiment, and FIG. 9B illustrates a photoelectronic device with multiple wavelengths actually manufactured in accordance with FIG. 9A.

As shown in FIG. 9B, when a (+) voltage is applied to the \textcircled{2} electrode of FIG. 9A and a (−) voltage is applied to the \textcircled{4} electrode, red light is emitted (FIG. 9C), and when a (+) voltage is applied to the \textcircled{3} electrode of FIG. 9A and a (−) voltage is applied to the \textcircled{4} electrode, green light is emitted (FIG. 9D). In addition, when a (+) voltage is applied to the \textcircled{1} electrode of FIG. 9A and a (−) voltage is applied to the \textcircled{4} electrode, blue light is emitted (FIG. 9E).

That is, according to an embodiment of the present invention, red, green and blue light are independently emitted using four electrodes (electrodes \textcircled{1}, \textcircled{2}, \textcircled{3} and \textcircled{4}), thereby providing a photoelectronic device with multiple wavelengths that minimizes the problem of color mixing, exhibits excellent electrical characteristics based on reduced problems of high driving voltage and leakage current, and realizes full-color RGB pixels.

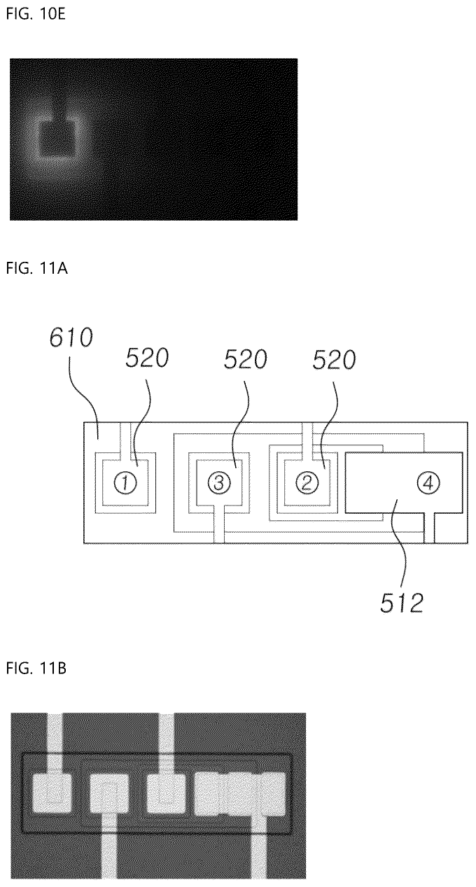

FIGS. 10A, 10B, 10C, 10D and 10E are images showing an actual implementation example of the photoelectronic device according to the fourth embodiment. FIG. 10A is a schematic diagram illustrating the formation of connection electrodes to the first electrode 510 and the second electrode 520 to drive the photoelectronic device according to the fourth embodiment, and FIG. 10B illustrates a photoelectronic device with multiple wavelengths actually manufactured in accordance with FIG. 10A.

As shown in FIG. 10B, when a (+) voltage is applied to the \textcircled{2} electrode of FIG. 10A and a (−) voltage is applied to the \textcircled{4} electrode, red light is emitted (FIG. 10C), and when a (+) voltage is applied to the \textcircled{3} electrode of FIG. 10A and a (−) voltage is applied to the \textcircled{4} electrode, green light is emitted (FIG. 10D). In addition, when a (+) voltage is applied to the \textcircled{1} electrode of FIG. 10A and a (−) voltage is applied to the \textcircled{4} electrode, blue light is emitted (FIG. 10E).

That is, according to an embodiment of the present invention, red, green and blue light are independently emitted using four electrodes (electrodes \textcircled{1}, \textcircled{2}, \textcircled{3} and \textcircled{4}), thereby providing a photoelectronic device with multiple wavelengths that minimizes the problem of color mixing, exhibits excellent electrical characteristics based on reduced problems of high driving voltage and leakage current, and realizes full-color RGB pixels.

FIGS. 11A, 11B, 11C, 11D, 11E and 11F are images showing an actual implementation example of the photoelectronic device as a function of voltage applied to the electrode in the fourth embodiment.

As shown in FIG. 11B, when a low voltage (+5V) is applied to the \textcircled{3} electrode of FIG. 11A, green light is emitted from the bottom of the \textcircled{3} electrode (FIG. 11C), and when a high voltage (+10V) is applied to the \textcircled{3} electrode, green light and blue light are emitted simultaneously from the bottom of the \textcircled{3} electrode, resulting in cyan light emission.

In addition, when a low voltage (+5V) is applied to the \textcircled{2} electrode of FIG. 11A, red light is emitted from the bottom of the \textcircled{2} electrode (FIG. 11E), and when a high voltage (+10 V) is applied to the \textcircled{2} electrode, red light and green light are emitted simultaneously from the bottom of the \textcircled{2} electrode, resulting in yellow light emission (FIG. 11F).

That is, the fourth embodiment of the present invention provides a photoelectronic device having multiple wavelengths, which emits monochromatic or mixed-colored light depending on the magnitude of the voltage applied to the electrode of each photo-device portion.

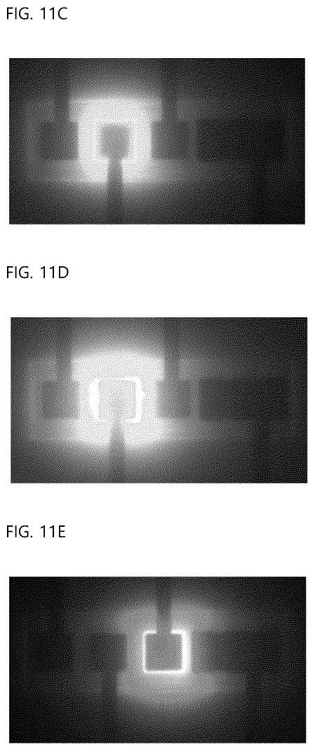

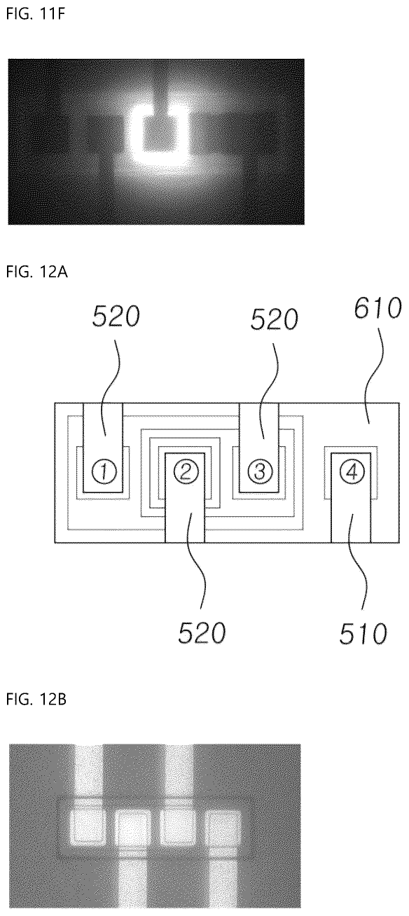

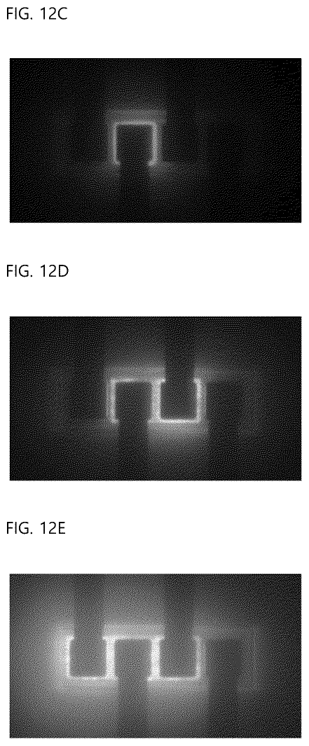

FIGS. 12A, 12B, 12C, 12D and 12E are images showing an actual implementation example of the photoelectronic device according to the fifth embodiment. FIG. 12A is a schematic diagram illustrating the formation of connection electrodes to the first electrode 510 and the second electrode 520 to drive the photoelectronic device according to the fifth embodiment, and FIG. 12B illustrates a photoelectronic device with multiple wavelengths actually manufactured in accordance with FIG. 12A.

As shown in FIG. 12B, when a (+) voltage is applied to the \textcircled{2} electrode of FIG. 12A and a (−) voltage is applied to the \textcircled{4} electrode, red light is emitted (FIG. 12C), and when a (+) voltage is applied to the \textcircled{3} electrode of FIG. 12A and a (−) voltage is applied to the \textcircled{4} electrode, green light is emitted (FIG. 12D). In addition, when a (+) voltage is applied to the \textcircled{1} electrode of FIG. 12A and a (−) voltage is applied to the \textcircled{4} electrode, blue light is emitted (FIG. 12E).

That is, according to an embodiment of the present invention, red, green and blue light are independently emitted using four electrodes (electrodes \textcircled{1}, \textcircled{2}, \textcircled{3} and \textcircled{4}), thereby providing a photoelectronic device with multiple wavelengths that minimizes the problem of color mixing, exhibits excellent electrical characteristics based on reduced problems of high driving voltage and leakage current, and realizes full-color RGB pixels.

In addition, in the fifth embodiment, the third photo-device portion 330 for red light and the second photo-device portion 320 for green light share the second common semiconductor layer 150 and the first semiconductor layer in the horizontal direction, and the first photo-device portion 310 for blue light shares the first common semiconductor layer 130 and the second common semiconductor layer 150 with other photo-device portions in the horizontal direction. In other words, the respective photo-device portions share the common semiconductor layer and the active layer horizontally with each other, so that the active layer area of the third photo-device portion 330 is limited to the third photo-device portion area and light emission occurs in the third photo-device portion area, the active layer 230 of the second photo-device portion 320 extends to the third photo-device portion area and light emission occurs in the third photo-device portion area and the second photo-device portion area, and the active layer 130 of the first photo-device portion 310 extends to the second photo-device portion area and the third photo-device portion area and light emission occurs in all of the third photo-device portion area, the second photo-device portion area and the first photo-device portion area.

As such, the present invention has the advantage of easy expansion of the light-emitting region based on the structure in which the respective photo-device portions share some of the common semiconductor layers and the active layers horizontally with each other. The area of the photo-device portion that has low luminous efficacy or is located far from the luminous surface is increased, as needed, the photo-device portion with low luminous efficacy can be reinforced, and the uniformity of color distribution and color reproduction can thus be improved.

As such, the photoelectronic device according to the embodiment of the present invention has an optimal structure that improves the spatial arrangement efficiency of electrodes and further increases the luminous efficacy by designing the shape and structure of photo-device portions and controlling open areas.

In addition, the present invention provides a full-color RGB pixel that exhibits excellent reproducibility over a large area and can be mass-produced by forming a plurality of photo-device layers, each including an active layer and a common semiconductor layer in a vertical direction, and forming a plurality of photo-device portions in a horizontal direction on a substrate by selective etching and opening processes.

In addition, by forming the photo-device portion such that the intermediate photo-device layer shares the common semiconductor layer with the upper and lower photo-device layers, it is possible to provide a photoelectronic device that has a compact structure, minimizes color mixing problems because RGB pixels can be implemented in a horizontal direction on a single substrate, and exhibits excellent electrical characteristics due to reduced problems of high driving voltage and current leakage.

In addition, the photoelectronic device according to one embodiment of the present invention has a structure in which the first electrodes are connected to each other to form a common electrode, or exhibits improved spreading effect of electrons and thus improved luminous efficacy because the area of the first electrode can be adjusted.

In addition, based on the structure in which the photo-device portions selectively share the common semiconductor layers, the photo-device portions can operate independently from or in conjunction with each other, and can easily operate one or more photo-device portions depending on the emission wavelength as needed, so that the light-emitting area can be easily controlled, the photo-device portion with low light-emitting efficiency can be reinforced and the uniformity of color distribution and color reproduction can be improved.

In addition, based on the structure in which the photo-device portions horizontally share some of the common semiconductor layers and the active layers with each other, the light-emitting area of each photo-device portion can be easily increased.

As apparent from the foregoing, the present invention provides a full-color RGB pixel that exhibits excellent reproducibility over a large area and can be mass-produced by forming a plurality of photo-device layers, each including an active layer and a common semiconductor layer in a vertical direction, and forming a plurality of photo-device portions in a horizontal direction on a substrate by selective etching and opening processes.

In addition, by forming the photo-device portion such that the intermediate photo-device layer shares the common semiconductor layer with the upper and lower photo-device layers, it is possible to provide a photoelectronic device that has a compact structure, minimizes color mixing problems because RGB pixels can be implemented in a horizontal direction on a single substrate, and exhibits excellent electrical characteristics due to reduced problems of high driving voltage and current leakage.

In addition, the photoelectronic device according to one embodiment of the present invention has a structure in which the first electrodes are connected to each other to form a common electrode, or exhibits improved spreading effect of electrons and thus improved luminous efficacy because the area of the first electrode can be adjusted.

In addition, based on the structure in which the photo-device portions selectively share the common semiconductor layers, the photo-device portions can operate independently from or in conjunction with each other, and can easily operate one or more photo-device portions depending on the emission wavelength as needed, so that the light-emitting area can be easily controlled, the photo-device portion with low light-emitting efficiency can be reinforced and the uniformity of color distribution and color reproduction can be improved.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A photoelectronic device having multiple wavelengths comprising:
a first photo-device layer comprising a lower semiconductor layer, a first active layer, and a first common semiconductor layer on a substrate, a second photo-device layer comprising a second active layer and a second common semiconductor layer on the first common semiconductor layer, and a third photo-device layer comprising a third active layer and an upper semiconductor layer on the second common semiconductor layer;
a first photo-device portion, a second photo-device portion and a third photo-device portion having the same or different emission wavelengths formed horizontally such that parts of the second common semiconductor layer, the first common semiconductor layer, and the lower semiconductor layer are sequentially opened; and
a first electrode formed on the lower semiconductor layer and a second electrode formed on each of the first photo-device portion, the second photo-device portion, and the third photo-device portion, or a first electrode formed in one area on the open lower semiconductor layer, first common semiconductor layer, and second common semiconductor layer, and a second electrode formed on each of the first photo-device portion, the second photo-device portion, and the third photo-device portion.

2. The photoelectronic device according to claim 1, wherein the first photo-device portion, the second photo-device portion and the third photo-device portion operate independently from one another.

3. The photoelectronic device according to claim 1, wherein the second photo-device portion and the third photo-device portion horizontally share at least one of the first common semiconductor layer or the second common semiconductor layer, and operate independently from or in conjunction with one another.

4. The photoelectronic device according to claim 1, wherein the second photo-device layer includes a plurality of second photo-device layers formed by repeatedly forming active layers between the common semiconductor layers.

5. The photoelectronic device according to claim 1, wherein the open area of the second common semiconductor layer and the first common semiconductor layer has any one shape of a polygon, a circle, an ellipse, or a bridge.

6. The photoelectronic device according to claim 5, wherein the first electrodes formed on the second common semiconductor layer, the first common semiconductor layer and the lower semiconductor layer are arranged on the same horizontal line and are connected to each other to form a common electrode.

7. The photoelectronic device according to claim 1, further comprising a passivation film opening an electrode area over an entire area of the photoelectronic device.

8. The photoelectronic device according to claim 7, wherein the first electrode formed on the lower semiconductor layer is connected to the first electrode formed in one area of the first common semiconductor layer and the second common semiconductor layer to form a common electrode.

9. The photoelectronic device according to claim 1, wherein the first electrode and the second electrode are formed to be flush with each other by adjusting the heights of the first electrode and the second electrode.

10. The photoelectronic device according to claim 1, wherein the substrate comprises silicon (Si), gallium arsenide (GaAs), gallium phosphide (GaP), gallium arsenide phosphide (GaAsP), boron nitride (BN), SiC, GaN, Zno, Mgo, InP, Ge, InAs, GaSb, sapphire, quartz, or glass.

11. The photoelectronic device according to claim 1, further comprising a buffer layer between the substrate and the lower semiconductor layer.

12. The photoelectronic device according to claim 11, wherein the buffer layer is a single layer containing any one material of GaAs, Un-GaN, AlN, AlGaN, InAlGaN, SiN, MgN, InN, InAs, AlAs, AlGaAs, InAlGaAs, GaP, InGaAsSb, InGaAsP, AlGaAsP, InGaAlAs, GaSb, AlSb, InAs, InSb, AlGaSb, AlInSb, GaInSb, GaInAsSb, or AlGaInSb, or comprises a plurality of layers including a combination of two or more layers, or a single layer containing two or more materials thereof or comprises a plurality of layers including a combination of two or more layers.

13. The photoelectronic device according to claim 1, wherein the lower semiconductor layer is an n-type semiconductor layer or a p-type semiconductor layer, and the upper semiconductor layer is a p-type semiconductor layer or an n-type semiconductor layer.

14. The photoelectronic device according to claim 13, wherein the n-type semiconductor layer is a single layer containing any one material of n-GaN, n-InGaN, n-AlGaN, n-InAlGaN, n-InAlGaP, n-GaAs, n-AlGaAs, n-InAlGaAs, n-AlGaAsP, n-InGaAsP, n-GaP, n-GaAsP, n-GaInP, n-AlGaInP, n-InGaP, n-InGaAsSb, n-InGaAsP, n-InGaAlAs, n-GaSb, n-AlSb, n-InAs, n-InSb, n-AlGaSb, n-AlInSb, n-GaInSb, n-GaInAsSb, or n-AlGaInSb, or comprises a plurality of layers including a combination of two or more layers, or is a single layer containing two or more materials thereof or comprises a plurality of layers including a combination of two or more layers, and
the p-type semiconductor layer is a single layer containing any one material of p-GaN, p-InGaN, p-AlGaN, p-InAlGaN, p-InAlGaP, p-GaAs, p-AlGaAs, n-InAlGaAs, p-AlGaAsP, p-InGaAsP, p-GaP, p-GaAsP, p-GaInP, p-AlGaInP, p-InGaP, p-InGaAsSb, p-InGaAsP, p-InGaAlAs, p-GaSb, p-AlSb, p-InAs, p-InSb, p-AlGaSb, p-AlInSb, p-GaInSb, p-GaInAsSb, or p-AlGaInSb, or comprises a plurality of layers including a combination of two or more layers, or is a single layer containing two or more materials thereof or comprises a plurality of layers including a combination of two or more layers.

15. The photoelectronic device according to claim 1, wherein the first active layer, the second active layer and the third active layer are formed by repeatedly depositing a plurality of layers containing a combination of two or more of GaN, InGaN, AlGaN, InAlGaN, InAlGaP, GaAs, AlGaAs, InAlGaAs, AlGaAsP, InGaAsP, GaP, GaAsP, GaInP, AlGaInP, InGaP, InGaAsSb, InGaAsP, InGaAlAs, GaSb, AlSb, InAs, InSb, AlGaSb, AlInSb, GaInSb, GaInAsSb, or AlGaInSb.

16. The photoelectronic device according to claim 1, wherein each of the first common semiconductor layer and the second common semiconductor layer comprises a tunnel junction layer.

17. The photoelectronic device according to claim 16, wherein the first common semiconductor layer and the second common semiconductor layer comprise an n-type semiconductor layer and a p-type semiconductor layer formed on and under the tunnel junction layer, respectively.

18. The photoelectronic device according to claim 17, further comprising:
a diffusion prevention layer or an electron blocking layer formed between the p-type semiconductor layer and the first active layer and between the p-type semiconductor layer and the second active layer, when the upper semiconductor layer is a p-type semiconductor layer.

19. The photoelectronic device according to claim 1, wherein the first electrode is formed in any one shape of a polygon, a circle, an ellipse, or a bridge.

20. The photoelectronic device according to claim 19, wherein the first electrodes are arranged on the same horizontal line and are connected to each other to form a common electrode.
